(19) United States
(12) Patent Application Publication
(10) Pub. No.: US 2024/0295821 A1
(43) Pub. Date: Sep. 5, 2024

(54) SUBSTRATE PROCESSING METHOD AND SUBSTRATE PROCESSING APPARATUS

(71) Applicant: Tokyo Electron Limited, Tokyo (JP)

(72) Inventors: Hiroyuki Fujii, Koshi City, Kumamoto (JP); Soichiro Okada, Koshi City, Kumamoto (JP); Yasuyuki Ido, Koshi City, Kumamoto (JP); Makoto Muramatsu, Koshi City, Kumamoto (JP); Keisuke Yoshida, Koshi City, Kumamoto (JP); Nanoka Miyahara, Koshi City, Kumamoto (JP)

(21) Appl. No.: 18/550,535

(22) PCT Filed: Feb. 21, 2022
(86) PCT No.: PCT/JP2022/007000

§ 371 Date: Sep. 14, 2023

(30) Foreign Application Priority Data
Mar. 15, 2021 (JP) 2021-041649
Feb. 17, 2022 (JP) 2022-022774

(51) Int. Cl. G03F 7/16; H01L 21/027

(52) U.S. Cl. CPC G03F 7/162; G03F 7/168; H01L 21/0274

(57) ABSTRACT

A substrate processing method includes forming a silicon carbide film on a spin on carbon film formed on a substrate; and forming a chemically amplified resist film for EUV on the silicon carbide film.

### TECHNICAL FIELD

The various aspects and embodiments described herein pertain generally to a substrate processing method and a substrate processing apparatus.

### BACKGROUND

Patent Document 1 discloses stacking a carbon film on a substrate to be processed, a silicon-containing intermediate film on the carbon film, and a photoresist film on the silicon-containing intermediate film. A spin on carbon film produced by spin-coating is used as the carbon film.

### PRIOR ART DOCUMENT

Patent Document 1: Japanese Patent Laid-open Publication No. 2013-228447

### DISCLOSURE OF THE INVENTION

### Problems to be Solved by the Invention

Exemplary embodiments provide a technique of appropriately transferring a resist pattern formed of a resist film for EUV to a spin on carbon film with a high throughput.

### Means for Solving the Problems

In an exemplary embodiment, a substrate processing method includes forming a silicon carbide film on a spin on carbon film formed on a substrate; and forming a chemically amplified resist film for EUV on the silicon carbide film.

### Effect of the Invention

According to the exemplary embodiments, it is possible to appropriately transcribe the resist pattern of the resist film for EUV to the spin on carbon film with the high throughput.

### BRIEF DESCRIPTION OF THE DRAWINGS

FIG. 1 is an explanatory diagram illustrating a schematic configuration of a wafer processing system having a coating and developing apparatus as a substrate processing apparatus according to an exemplary embodiment.

FIG. 2 is an explanatory diagram schematically illustrating an internal configuration of the coating and developing apparatus.

FIG. 3 is a diagram schematically illustrating the internal configuration on a front side of the coating and developing apparatus.

FIG. 4 is a diagram schematically illustrating the internal configuration on a rear side of the coating and developing apparatus.

FIG. 5 is a diagram for describing a structure of a SiC film formed in the coating and developing apparatus.

FIG. 6 is a diagram for describing the structure of the SiC film formed in the coating and developing apparatus.

FIG. 7 is a longitudinal cross sectional view illustrating a schematic configuration of a SiC film coating unit.

FIG. 8 is a transversal cross sectional view illustrating the schematic configuration of the SiC film coating unit.

FIG. 9 is a longitudinal cross sectional view illustrating a schematic configuration of a radiation unit.

FIG. 10 is a flowchart illustrating main processes of an example of a wafer processing.

FIG. 11A to FIG. 11F are schematic partial cross sectional views illustrating states of a wafer W after being subjected to the respective processes of the wafer processing.

FIG. 12 shows an example of a process window for explaining a difference in a resist pattern caused by a change in a film type of a base film of a resist film.

FIG. 13 shows an example of a process window for explaining a difference in a resist pattern caused by a change in a film type of the base film of the resist film.

FIG. 14 is a diagram showing a relationship between a hole diameter and a number of shape defects of a pattern when a hole pattern is formed of a chemically amplified EUV resist film.

### DETAILED DESCRIPTION

In a manufacturing process for a semiconductor device, various processings such as a photolithography processing and an etching processing are performed on a semiconductor wafer (hereinafter, simply referred to as “wafer”) which is as a substrate. In the etching processing, an etching target is etched by using, as a mask, a resist pattern formed by the photolithography processing. Types of the etching include a wet etching using a liquid and a dry etching using a gas.

In the dry etching, when selectivity of an etching target film with resist to the resist pattern is low and the resist pattern is thin, a carbon-containing hard mask film, a silicon-containing film, and a resist film may be sequentially stacked on the etching target film. When these films are stacked in this way, the resist pattern is transcribed, by the dry etching, to the silicon-containing film, the carbon-containing hard mask film, and the etching target film in this order. The carbon-containing hard mask film may be a spin on carbon (SoC) film, and the silicon-containing film may be a silicon dioxide (SiO₂) film.

In recent years, to meet a trend of higher integration of semiconductor devices, the resist pattern needs to be miniaturized. Thus, in order to achieve the miniaturization of the resist pattern, an exposure processing using EUV (Extreme Ultraviolet) light has been proposed. Further, a resist film for EUV (EUV resist film) needs to be made very thin. For example, this EUV resist film needs to have a film thickness of 50 nm or less.

In addition, when the SoC film as the carbon-containing hard mask film, the SiO₂ film as the silicon-containing film, and the EUV resist film are sequentially stacked, a pattern collapse may occur due to low adhesion of the resist film to the SiO₂ film. Therefore, an adhesion layer may be formed on the SiO₂ film before the formation of the resist film in order to improve the adhesion of the EUV resist film to a base film. However, since the formation of the adhesion layer in this way causes an increase of the number of processes required, there is a room for improvement in terms of a throughput.

In view of the foregoing, the present disclosure provides a technique capable of appropriately transcribing the resist pattern of the EUV resist film to the SoC film with a high throughput.

Hereinafter, a substrate processing apparatus and an inspection method according to an exemplary embodiment will be described with reference to the accompanying drawings. Further, in the present specification and the drawings, parts having substantially same functions and configurations will be assigned same reference numerals, and redundant description will be omitted.

### <Wafer Processing System>

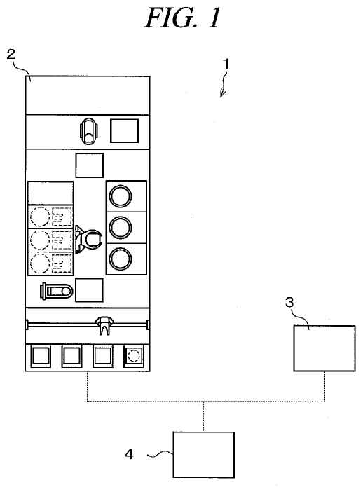

FIG. 1 is an explanatory diagram illustrating a schematic configuration of a wafer processing system having a coating and developing apparatus as the substrate processing apparatus according to the exemplary embodiment.

A wafer processing system 1 of FIG. 1 is equipped with a coating and developing apparatus 2, an etching apparatus 3, and a control device 4.

The coating and developing apparatus 2 is configured to perform a photolithography processing on a wafer. In this coating and developing apparatus 2, formation of a resist film or the like is performed.

The etching apparatus 3 is configured to perform a dry etching processing on the wafer. As the etching apparatus 3, a RIE (Reactive lon Etching) apparatus configured to perform the dry etching processing on the wafer by a plasma processing is used, for example. This etching apparatus 3 performs, for example, etching of a base film of the resist film by using the resist film as a mask.

The control device 4 is configured to control operations of the individual apparatuses. The control device 4 is, for example, a computer equipped with a CPU, a memory, and the like, and has a program storage (not shown). The program storage stores therein a program for controlling the operations of the aforementioned various processing apparatuses or a driving system such as transfer devices (not shown) to perform a wafer processing to be described later in the wafer processing system 1. Further, the program may be recorded in a computer-readable non-transitory recording medium H, and may be installed from the recording medium H to the control device 4. A part or the whole of the program may be implemented by dedicated hardware (circuit board).

### <Coating and Developing Apparatus>

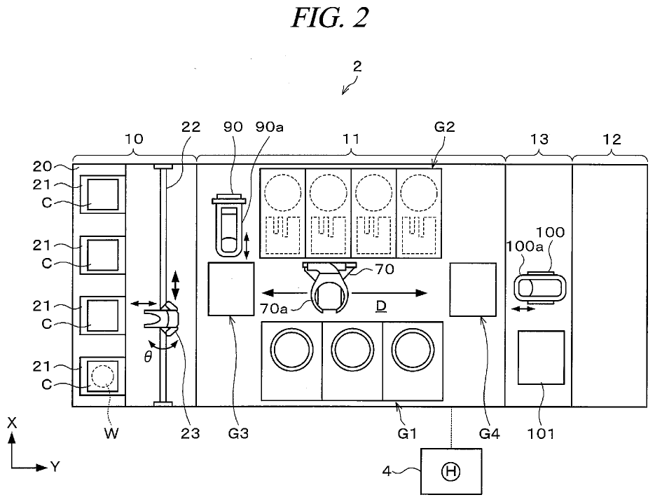

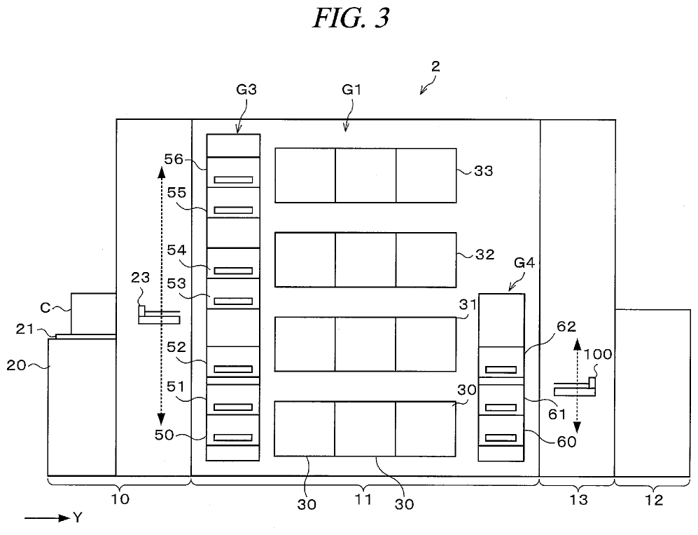

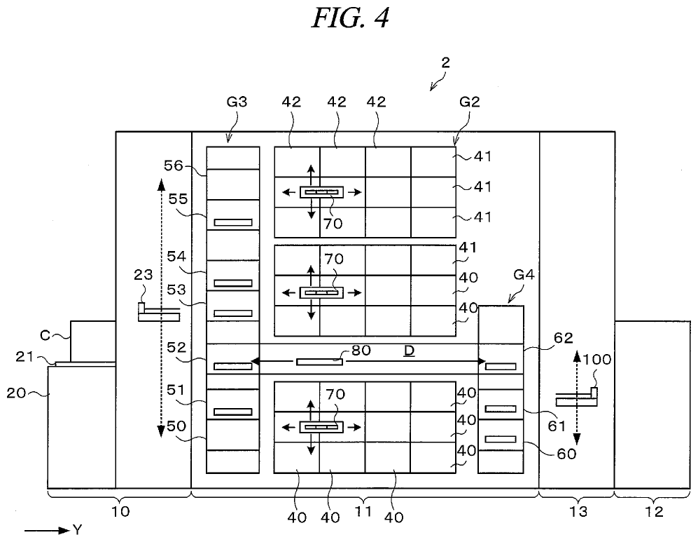

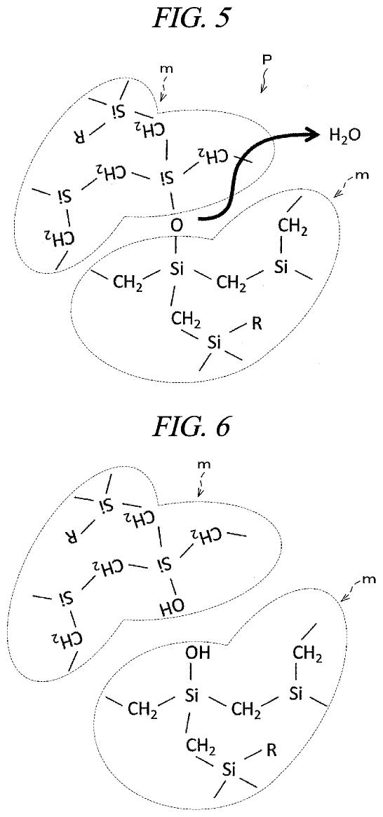

FIG. 2 is an explanatory diagram schematically illustrating an internal configuration of the coating and developing apparatus 2. FIG. 3 and FIG. 4 are diagrams schematically illustrating the internal configuration on a front side and a rear side of the coating and developing apparatus 2, respectively. FIG. 5 and FIG. 6 are diagrams for describing a structure of a SiC film formed in the coating and developing apparatus 2.

As shown in FIG. 2, the coating and developing apparatus 2 includes a cassette station 10 in which cassettes C each accommodating a plurality of wafers W therein are carried in and out; and a processing station 11 equipped with various kinds of processing units configured to perform preset processings on the wafer W. The coating and developing apparatus 2 has a configuration in which the cassette station 10, the processing station 11, and an interface station 13 configured to transfer the wafers W to/from an exposure apparatus 12 adjacent to the processing station 11 are connected as one body.

The cassette station 10 is equipped with a cassette placing table 20. The cassette placing table 20 is provided with a plurality of cassette placing plates 21 for placing thereon the cassettes C when the cassettes C are carried to/from the outside of the coating and developing apparatus 2.

The cassette station 10 is equipped with a wafer transfer unit 23 configured to be moved on a transfer path 22 extending in the X-axis direction in the drawing. The wafer transfer unit 23 is also movable in a vertical direction and pivotable around a vertical axis (θ direction), and is capable of transferring the wafer W between the cassette C on the cassette placing plate 21 and a transit unit of a third block G3 of the processing station 11 to be described later.

The processing station 11 is equipped with a plurality of, for example, four blocks G1, G2, G3, G4 including various units. For example, the first block G1 is disposed on the front side (negative X-axis side in FIG. 2) of the processing station 11, and the second block G2 is disposed on the rear side (positive X-axis side in FIG. 2) of the processing station 11. Further, the third block G3 is disposed on the cassette station 10 side (negative Y-axis side in FIG. 2) of the processing station 11, and the fourth block G4 is disposed on the interface station 13 side (positive Y-axis side in FIG. 2) of the processing station 11.

In the first block G1, a plurality of liquid processing units, for example, a developing unit 30, an SoC film coating unit 31, a SiC film coating unit 32, a resist coating unit 33 are arranged in this order from the bottom, as depicted in FIG. 3.

The developing unit 30 is configured to perform a developing processing on the wafer W.

The SoC film coating unit 31 is configured to directly coat a SoC film material onto an etching target film (for example, a silicon oxide film) formed on the wafer W to form a coating film of the SoC film material. The coating film of the SoC film material becomes a SoC film by being heated with a heat treatment unit 40 to be described later. Further, a carbon (C) content of the SoC film is equal to or higher than 90%. In the present exemplary embodiment, the SoC film coating unit 31 and the heat treatment unit 40 constitute a “spin on carbon film forming unit”.

The SiC film coating unit 32 is configured to directly coat a silicon carbide (SiC) film material onto the SoC film formed on the wafer W, thus forming a coating film of the SiC film material. The coating film of the SiC film material becomes a SiC film by being heated with the heat treatment unit 40 to be described later and radiated with an ultraviolet ray from a radiation unit 41 to be described later. The SiC film formed in this way has a C content of 30% to 70% or more. In the present exemplary embodiment, the SiC film coating unit 32 and the heat treatment unit 40 constitute a “silicon carbide film forming unit”.

As an example of the SiC film material, a material containing polycarbosilane as a material containing a Si—C bond where a silicon (Si) atom and a carbon (C) atom are bonded is used.

In the present exemplary embodiment, in terms of structure, the SiC film is a film in which the ratio of C atoms as atoms bonded to Si atoms is higher than that of oxygen (O) atoms. In the Si-containing film formed on the wafer W, the atoms bonded to Si atoms have a high degree of influence on the characteristics required for the Si-containing film, so that the SiC film is distinguished from a film expressed by a combination of Si and other elements, such as a SiOx film, due to a difference in atoms other than Si intentionally left in the Si-containing film or a difference in a bonding state between these atoms and the Si atoms. That is, the SiC film has film characteristics different from those of a film expressed by a combination of Si and other elements, such as a SiOx film. Characteristics of a film include, by way of example, a difference in etching resistance with respect to another film stacked on either top or bottom of the film, a difference in reaction when light is radiated thereto, and so forth. These film characteristics can be a process factor that can influence a process result in an overall processing.

In the present exemplary embodiment, a main structural portion of the SiC film having both Si atoms and C atoms is an aggregate P of portions m where the Si atoms are bonded to each other with the C atom therebetween, as shown in FIG. 5. Further, in the SiC film, if a coating portion for the SiC film, such as an additive contained in the SiC film material, which is unnecessary in terms of the film characteristics, remains, the unnecessary portion is not included in the “main structural portion”.

More specifically, the main structural portion of the SiC film has the following structure. That is, the main structural portion has a structure in which a plurality of portions m, in which the Si atoms are bonded to each other with the C atom therebetween, which originally exist independently of each other as shown in FIG. 6, are bonded by dehydration condensation, as illustrated in FIG. 5. The portion m in which the Si atoms are bonded to each other with the C atom therebetween before the dehydration condensation is, for example, polycarbosilane. In other words, the SiC film is formed as a result of the dehydration condensation of the polycarbosilane in the coating film of the SiC film material.

In addition, in the main structural portion of the SiC film, except the atoms that constitute a siloxane bond (Si—O—Si bond), the atom bonded to the Si atom does not include an O atom but includes a C atom.

The resist coating unit 33 is configured to coat a chemically amplified resist liquid for EUV on the SiC film formed on the wafer W to form a coating film of the resist liquid. The coating film of the resist liquid becomes a resist film by being heated with the heat treatment unit 40 to be described later. In the present exemplary embodiment, the resist coating unit 33 and the heat treatment unit 40 constitute a “resist film forming unit”.

For example, three developing units 30, three SOC film coating units 31, three SiC film coating units 32, and three resist coating units 33 are respectively arranged in a row in a horizontal direction, respectively. In addition, the number and the layout of these developing units 30, SoC film coating units 31, SiC film coating units 32, and resist coating units 33 are not particularly limited and may be selected as required.

Moreover, in the SoC film coating unit 31, the SiC film coating unit 32, and the resist coating unit 33, the coating film of the SoC film material, the coating film of the SiC film material, and the coating film of the chemically amplified resist liquid for EUV are formed on the wafer W by a spin coating method.

The second block G2 is equipped with the heat treatment unit 40 and the radiation unit 41, as illustrated in FIG. 4.

The heat treatment unit 40 is configured to perform a heat treatment such as heating and cooling of the wafer W.

The radiation unit 41 is configured to radiate ultraviolet rays to the coating film of the SiC film material formed on the wafer W in a low-oxygen atmosphere with an oxygen concentration of 0.1% or less. The radiation of the ultraviolet rays by the radiation unit 41 is performed before the formation of the resist film.

Each of the heat treatment unit 40 and the radiation unit 41 may be plural in number, and they are respectively arranged in a vertical direction and a horizontal direction. The number and the layout of these heat treatment units 40 and radiation units 41 may be selected as required.

For example, the third block G3 is equipped with a multiple number of transit units 50, 51, 52, 53, 54, 55, and 56 that are arranged in order from the bottom. Further, the fourth block G4 is equipped with a plurality of transit unit 60, 61, and 62 that are arranged in order from the bottom.

As shown in FIG. 2, a wafer transfer region D is formed in a region surrounded by the first block G1 to the fourth block G4. A wafer transfer unit 70 is disposed in this wafer transfer region D.

The wafer transfer unit 70 has a transfer arm 70a configured to be moved in the Y-axis direction, the X-axis direction, the θ direction, and a vertical direction. The wafer transfer unit 70 is moved in the wafer transfer region D to transfer the wafer W between the ambient units in the first block G1, the second block G2, the third block G3 and the fourth block G4. The wafer transfer unit 70 is plural in number, and these wafer transfer units 70 are vertically arranged as shown in FIG. 4, for example, to transfer the wafer W between the units on a substantially level with each other in the blocks G1 to G4, for example.

Further, the wafer transfer region D is equipped with a shuttle transfer unit 80 configured to transfer the wafer W linearly between the third block G3 and the fourth block G4.

The shuttle transfer unit 80 is configured to be linearly moved in the Y-axis direction of FIG. 4, for example. The shuttle transfer unit 80 is moved in the Y-axis direction while supporting the wafer W thereon to thereby transfer the wafer W between the transfer unit 52 of the third block G3 and the transfer unit 62 of the fourth block G4.

As illustrated in FIG. 2, a wafer transfer unit 90 is provided next to the third block G3 on the positive X-axis side. The wafer transfer unit 90 has a transfer arm 90a configured to be movable in the X-axis direction, the θ direction, and a vertical direction, for example. The wafer transfer unit 90 is moved up and down while supporting the wafer W thereon to thereby transfer the wafer W to the respective transit units in the third block G3.

The interface station 13 is provided with a wafer transfer unit 100 and a transit unit 101. The wafer transfer unit 100 has a transfer arm 100a configured to be movable in the Y-axis direction, the θ direction, and a vertical direction, for example. The wafer transfer unit 100 is capable of transferring the wafer W between the respective transit units in the fourth block G4, the transit unit 101, and the exposure apparatus 12, while supporting the wafer W on the transfer arm 100a.

In the coating and developing apparatus 2, the respective processing units and transfer units described above are controlled by, for example, the control unit 4.

### <SiC Film Coating Unit>

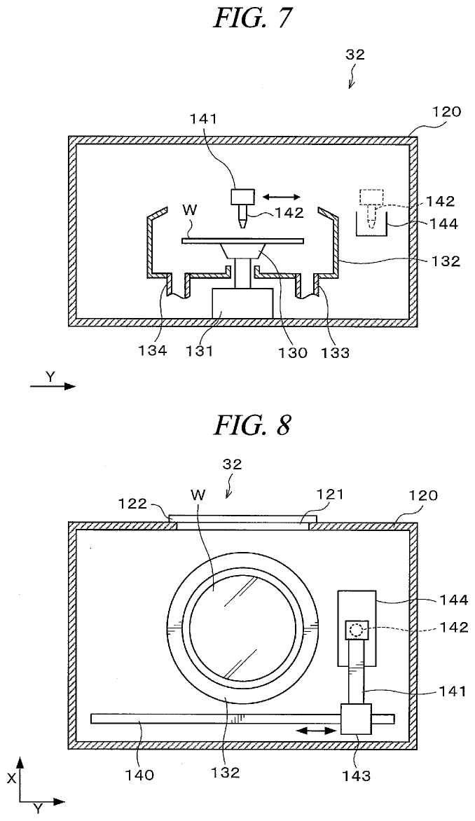

Now, a configuration of the aforementioned SiC film coating unit 32 will be explained. FIG. 7 and FIG. 8 are respectively a longitudinal cross sectional view and a transversal cross sectional view schematically illustrating the configuration of the SiC film coating unit 32.

The SiC film coating unit 32 is equipped with a processing vessel 120 having a hermetically sealable inside, as shown in FIG. 7. A carry-in/out opening 121 for the wafer W is formed at a side surface of the processing vessel 120, and an opening/closing shutter 122 is provided at the carry-in/out opening 121, as illustrated in FIG. 8.

As shown in FIG. 7, a spin chuck 130 configured to hold and rotate the wafer W is disposed in a central portion of the processing vessel 120. The spin chuck 130 has a horizontal top surface, and a suction opening (not shown) for suctioning the wafer W, for example, is provided in the top surface. By being suctioned through this suction opening, the wafer W can be attracted to and held on the spin chuck 130.

The spin chuck 130 is connected to a chuck driving mechanism 131 and can be rotated at a required speed by the chuck driving mechanism 131. The chuck driving mechanism 131 has a rotational driving source (not shown) such as a motor configured to generate a driving force for the rotation of the spin chuck 130. Further, the chuck driving mechanism 131 is also provided with an elevational driving source such as a cylinder, so the spin chuck 130 can be moved up and down.

A cup 132 is disposed around the spin chuck 130 to receive and collect a liquid scattered or falling from the wafer W. A drain pipe 133 through which the collected liquid is drained and an exhaust pipe 134 through which an atmosphere inside the cup 132 is exhausted are connected to a bottom surface of the cup 132.

As depicted in FIG. 8, a rail 140 extending along the Y-axis direction (left-right direction in FIG. 8) is provided on the negative X-axis side (lower side in FIG. 8) of the cup 132. For example, the rail 140 is provided to extend from the outside of the cup 132 on the negative Y-direction side (left side in FIG. 8) to the outside of the cup 132 on the positive Y-axis side (right side in FIG. 8). The rail 140 has an arm 141 mounted thereto.

A coating nozzle 142 is supported by the arm 141, as shown in FIG. 7 and FIG. 8. The coating nozzle 142 is configured to discharge the SiC film material as a coating liquid. The arm 141 is movable on the rail 140 by a nozzle driving unit 143 shown in FIG. 8. Accordingly, the coating nozzle 142 can be moved from a standby unit 144 provided outside the cup 132 on the positive Y-axis side to a position above a central portion of the wafer W within the cup 132, and also can be moved above a front surface of the wafer in a radial direction of the wafer W. In addition, the arm 141 can be moved up and down by the nozzle driving unit 143 to adjust the height of the coating nozzle 142. The coating nozzle 142 is connected to a supply (not shown) configured to supply an MSQ to the coating nozzle 142.

Further, each of the developing unit 30, the SoC film coating unit 31, and the resist coating unit 33 has the same configuration as the SiC film coating unit 32 except that the types of processing liquids discharged from the coating nozzle 142 are different.

### <Radiation Unit>

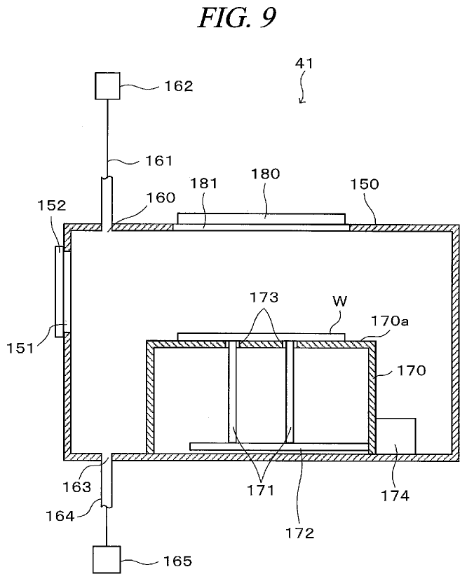

Now, a configuration of the aforementioned radiation unit 41 will be discussed. FIG. 9 is a longitudinal cross sectional view schematically illustrating the configuration of the radiation unit 41.

The radiation unit 41 is equipped with a processing vessel 150 having a hermetically sealable inside, as illustrated in FIG. 9. On one side of the processing vessel 150 facing the wafer transfer region D, a carry-in/out opening 151 for the wafer W is formed, and an opening/closing shutter 152 is provided at the carry-in/out opening 151.

A gas supply port 160 is formed at a top surface of the processing vessel 150 to supply a gas other than an oxygen gas, for example, an inert gas such as a N₂ gas toward the inside of the processing vessel 150. This gas supply port 160 is connected to a gas supply mechanism 162 via a gas supply line 161. The gas supply mechanism 162 includes, for example, a flow rate control valve (not shown) configured to adjust a gas supply flow rate into the processing vessel 150.

By supplying the gas other than the oxygen gas into the processing vessel 150 with the gas supply mechanism, the inside of the processing vessel 150 can be set to be in a low-oxygen atmosphere with an oxygen concentration of 0.1 ppm or less.

For example, an exhaust port 163 through which the atmosphere inside the processing vessel 150 is exhausted is formed at a bottom surface of the processing vessel 150, and this exhaust port 163 is connected via an exhaust line 164 to an exhaust mechanism 165 configured to exhaust an atmosphere inside the processing vessel 150. The exhaust mechanism 165 has an exhaust pump (not shown) or the like.

By supplying the gas other than the oxygen gas through the gas supply port 160 and exhausting it through the exhaust port 163, the atmosphere inside the processing vessel 150 can be quickly replaced with the low-oxygen atmosphere of 0.1 ppm or less.

A cylindrical supporting body 170 on which the wafer W is horizontally placed is provided inside the processing vessel 150. Inside the supporting body 170, elevating pins 171 for delivering the wafer W are supported by a supporting member 172. The elevating pins 171 are disposed so as to pass through through holes 173 formed in a top surface 170a of the supporting body 170. For example, there are three of them. A driving mechanism 174 configured to elevate the supporting member 172 up and down to move the elevating pins 171 up and down is provided at a base end of the supporting member 172. The driving mechanism 174 has a driving source (not shown) such as a motor configured to generate a driving force for elevating the support member 172 up and down.

Above the processing chamber 150, there is provided a light source 180 such as a deuterium lamp or an excimer lamp configured to radiate ultraviolet rays having a wavelength of 172 nm to the wafer W on the supporting body 170. The light source 180 may radiate the ultraviolet rays to the entire surface of the wafer W. A window 181 through which the ultraviolet rays from the light source 180 are transmitted is provided at a ceiling plate of the processing vessel 150. Here, the wavelength of the ultraviolet rays is not limited to 172 nm, and it may be in the range of, e.g., 150 nm to 250 nm.

### <Wafer Processing>

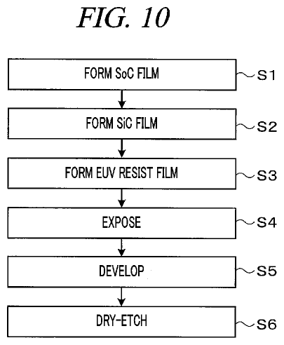

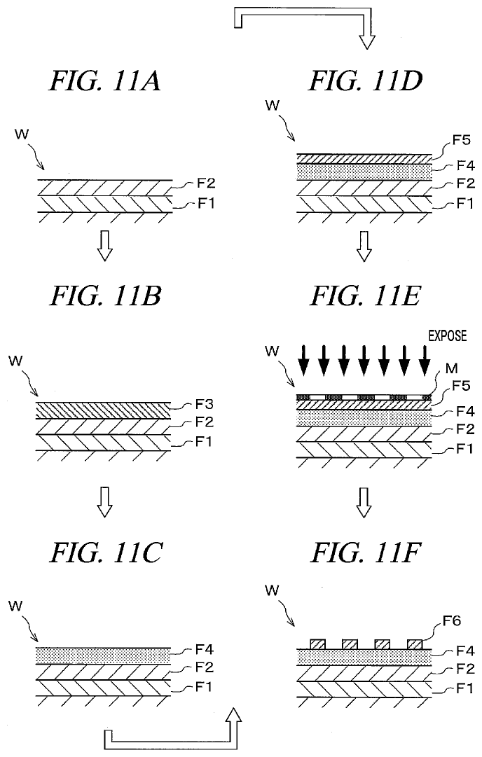

Now, a wafer processing performed by using the wafer processing system 1 configured as described above will be described. FIG. 10 is a flowchart showing main processes of one example of the wafer processing. FIG. 11A to FIG. 11F are schematic partial cross sectional views illustrating states of the wafer W after being subjected to the respective processes of the wafer processing. Here, as illustrated in FIG. 11A, a SiO₂ film F1 as an etching target is formed in advance on the front surface of the wafer W which is to be subjected to the wafer processing.

In the wafer processing using the wafer processing system 1, first, the cassette C accommodating therein the plurality of wafers W is carried into the cassette station 10 of the coating and developing apparatus 2. Then, the wafer W in the cassette C is transferred to the processing station 11, and is temperature-controlled in the heat treatment unit 40.

### (Process S1)

Thereafter, as depicted in FIG. 10 and FIG. 11A, a SoC film F2 is formed directly on the SiO₂ film F1 that is formed on the wafer W.

To elaborate, the wafer W is transferred to the SoC film coating unit 31, and the SoC film material is spin-coated on the front surface of the wafer W, so that the coating film of the SoC film material is formed so as to cover the SiO₂ film F1.

Subsequently, the wafer W is transferred to the heat treatment unit 40, and the coating film of the SoC film material is heated, so that the SoC film F2 is formed. The SoC film F2 thus formed has a thickness of, e.g., 50 nm to 100 nm.

### (Process S2)

Next, a SiC film is directly formed on the SoC film F2 formed on the wafer W.

To elaborate, the wafer W is transferred to the SiC film coating unit 32, and the SiC film material containing the polysilane carbon, for example, is spin-coated on the front surface of the wafer W, so that a coating film F3 of the SiC film material is formed so as to cover the SoC film F2, as illustrated in FIG. 11B.

Subsequently, the wafer W is transferred to the heat treatment unit 40 to be heated. Specifically, the coating film F3 of the SiC film material is heated in an atmospheric atmosphere. Here, a heating temperature is in the range of, e.g., 200° C. to 250° C.

After being heated, the wafer W is transferred to the radiation unit 41. Then, the coating film F3 of the SiC film material is radiated with the ultraviolet rays in the low-oxygen atmosphere with the oxygen concentration of 0.1% or less. Specifically, in the low-oxygen atmosphere with the oxygen concentration of 0.1%, the ultraviolet rays of a preset dose are radiated to the entire top surface of the coating film F3 of the SiC film material. Here, if the oxygen concentration is not low, ozone may be generated by the ultraviolet radiation, so that the Si—C bond of the polycarbosilane may be cut by this ozone. For this reason, the ultraviolet radiation is performed in the low-oxygen atmosphere.

During the series processes of the heating and the ultraviolet radiation described above, the dehydration condensation reaction proceeds between the polycarbosilanes in the SiC film material. Thus, the SiC film F4 formed on the SoC film F2 as shown in FIG. 11C has a film thickness of 5 nm to 30 nm and a carbon content of 30% to 70%, for example.

### (Process S3)

Thereafter, as shown in FIG. 11D, a chemically amplified resist film F5 for EUV is formed directly on the SiC film formed on the wafer W.

To elaborate, the wafer W is transferred to the resist coating unit 33, and a chemically amplified resist liquid for EUV is spin-coated on the front surface of the wafer W, so that the coating film of the chemically amplified resist liquid for EUV is formed so as to cover the SiC film F4.

Subsequently, the wafer W is transferred to the heat treatment unit 40 and subjected to a pre-bake processing, so that the chemically amplified resist film F5 for EUV is formed. The resist film F5 thus formed has a film thickness of 30 nm to 100 nm.

Through the processes S1 to S3, the SoC film F2, the SiC film F4, and the resist film F5 are successively formed on the wafer W in this order from the bottom (that is, such that no other films exist between these films).

### (Process S4)

Next, the resist film F5 formed on the wafer W is subjected to an exposure processing.

To elaborate, the wafer W is transferred to the exposure apparatus 12 via the interface station 13, and an exposure processing using a mask M is performed on the wafer W, so that the resist film on the wafer W is exposed into a required pattern, as shown in FIG. 11E.

### (Process S5)

Then, the exposed resist film F5 formed on the wafer W is developed, so that a resist pattern F6 is formed, as shown in FIG. 11F.

Specifically, after being exposed, the wafer W is transferred to the heat treatment unit 40 to be subjected to a post-exposure bake processing.

Then, the wafer W is transferred to the developing unit 30 to be subjected to a developing processing, so that the resist pattern F6 is formed. After the pattern is formed, the wafer W is transferred to the heat treatment unit 40 to be subjected to a post-bake processing.

Thereafter, the wafer W is accommodated in the cassette C, and transferred to the etching apparatus 3.

### (Process S6)

Afterwards, the dry etching is performed in the etching apparatus 3.

Specifically, dry etching (first dry etching) of the SiC film F4 is performed by using the resist pattern F6 as a mask. Subsequently, dry etching (second dry etching) of the SoC film F2 is performed by using, as a make, the SiC film F4 to which the pattern is transcribed by the first dry etching. Then, dry etching (third dry etching) of the SiO₂ film F1 as the etching target is performed by using, as a mask, the SoC film F2 to which the pattern is transcribed by the second dry etching. Further, the first to third dry etchings are performed in different processing vessels.

Through the above-described processes, the wafer processing using the wafer processing system 1 is completed.

### <Effects>

As described above, in the present exemplary embodiment, the films are formed on the SoC film formed on the wafer W in the order of the SiC film and the chemically amplified resist film for EUV from the bottom. In other words, in the present exemplary embodiment, the SiC film is formed on the SoC film formed on the wafer W, and the chemically amplified resist film for EUV is formed on the SiC film.

The SiC film has C atoms, the same as the SoC film, but the C content of the SiC film is lower than that of the SoC film. Further, the main structural portion of the SiC film having both Si atoms and C atoms is the aggregate P of the portions m in which the Si atoms are bonded to each other with the C atom therebetween. More specifically, in the SiC film, the C atoms form carbosilane bonds (Si—C bonds). Therefore, the SiC film and the SoC film have completely different atomic arrangement structures, so the two are different substances. Therefore, the SiC film has high etching selectivity with respect to the SoC film. Further, the etching selectivity of the SiC film with respect to the SoC film is equal to the etching selectivity of the SO₂ film with respect to the SoC film or higher than the etching selectivity of the SO₂ film with respect to the SoC film. Moreover, for the same reason as described above, etching selectivity of the resist pattern with respect to the SiC film is high.

Furthermore, the SiC film has high adhesion to the resist pattern. The reason for this will be described later.

Therefore, the resist pattern of the chemically amplified resist film for EUV can be appropriately transcribed to the SoC film.

In addition, in the present embodiment, it is only the one layer of SiC film that is formed on the SoC film before the formation of the resist film for EUV. Thus, as compared to a case where the films are formed on the SoC film in the order of the SiO₂ film and the adhesion layer before the formation of the resist film for EUV, the high throughput can be achieved according to the present exemplary embodiment.

That is, according to the present exemplary embodiment, the resist pattern of the resist film for EUV can be appropriately transcribed to the SoC film with the high throughput.

Moreover, in the present exemplary embodiment, in the coating and developing apparatus 2, the SiC film is formed, and the chemically amplified resist film for EUV is then formed. That is, in the present exemplary embodiment, the time from the formation of the SiC film to the formation of the resist film is short. Therefore, it is possible to suppress the deterioration of the SiC film before the formation of the resist film.

### <The Reason why SiC Film has High Adhesion to Resist Pattern>

The energy required for the resist pattern to collapse when a developing liquid is supplied to a surface of the resist pattern may be calculated as adhesion work. The adhesion work can be represented by the following expression.

$$Adhesion work = γ LR + γ SL - γ SR$$

γLR: a difference in surface free energy between the developing liquid and the resist film
γSL: a difference in surface free energy between the developing liquid and the base film of the resist film formed on the wafer W
γSR: a difference in surface free energy between the base film of the resist film formed on the wafer W and the resist film

In order to suppress the collapse of the resist pattern, it is desirable to set a large adhesion work. Therefore, it is desirable that the γSL is large and the γSR is small. Regarding this point, the inventors of the present application have conducted intensive experiments and the like, and it is confirmed that when a carbon-based film is used as a base film of the chemically amplified resist material for EUV lithography, the surface free energy of the base film can be made close to that of the resist material, that is, it is possible to reduce the γSR. It is also confirmed that the carbon-based film is able to secure the difference in surface free energy from that of the developing liquid to some extent, that is, it is possible to increase the γSL to some extent.

Further, since the SiC film is a carbon-based film, the γSL is large and the γSR is small. Thus, the adhesion work can be increased. Therefore, the SiC film can suppress the collapse of the resist pattern, in other words, the SiC film has high adhesion to the resist pattern.

### <Evaluation Test>

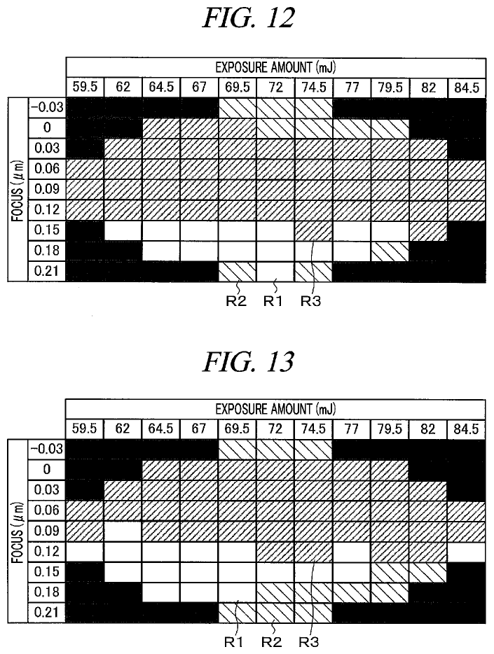

FIG. 12 and FIG. 13 are diagrams showing examples of evaluation results for the collapse of the resist pattern in the case where the SiC film is formed by the method according to the present exemplary embodiment. FIG. 12 and FIG. 13 show examples of a process window in which an exposure amount and a focus amount are varied when forming a pattern of the chemically amplified EUV resist film to have a predetermined height on a target substrate. FIG. 12 illustrates a case where a film formed between the SoC film and the EUV resist film of the target substrate, that is, a base film is a silicon-containing antireflection film (SiARC film), and FIG. 13 illustrates a case where the base film is a SiC film. When forming the SiC film as the base film, the oxygen concentration at the time of the ultraviolet radiation to the coating film of the SiC film material is set to 400 ppm. The reason for this is as follows. That is, although it is desirable that the oxygen concentration at the time of the ultraviolet radiation is set to be 0.1%, the oxygen concentration is set to 400 ppm, which is equivalent to approximately ½ of 0.1%, in order to enhance reliability of the processing on the entire surface by allowing a sufficient margin on the oxygen concentration, while suppressing the time for correcting the atmosphere of the low-oxygen condition. In addition, the formation, the exposure, and the development of the resist film are performed under the same conditions except for the film type of the base film of the EUV resist film, and the results are evaluated. Furthermore, in order to check the possibility of the pattern collapse, the thickness of the EUV resist film is set to be 60 nm, which is about 20 nm thicker than a normally assumed thickness. Further, as the resist pattern, the pattern having a pitch of about 20 nm is formed.

A region R1 (a region where a cell is white) shown in FIG. 12 and FIG. 13 is a region where no damage in the resist pattern is observed. Further, a region R2 is a region where the pattern collapse is observed, and a region R3 is a region where the pattern itself has collapsed. As can be seen from FIG. 12 and FIG. 13, when the SiARC film is formed, the pattern itself has collapsed under a condition of the focus amount of 0.08 μm or 0.12 μm. However, when the SiC film is formed, the pattern collapse does not occur even under a condition of a quite wide range of the exposure amount. In this way, by forming the SiC film as the base film, the collapse of the resist pattern and the like can be suppressed.

In addition, when the above-described evaluation is performed, the width of the pattern is also measured. According to this measurement result, the larger the exposure amount and the larger the focus amount, the narrower the pattern may be, and, in overall, the pattern consequently tends to collapse easily.

### Modification Examples

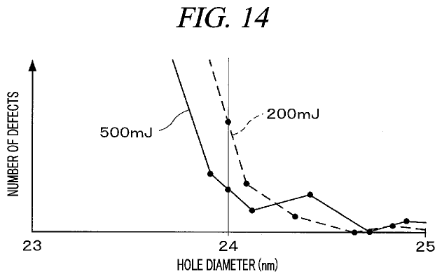

FIG. 14 is a diagram showing a relationship between a hole diameter and a number of shape defects of a pattern when a hole pattern is formed of the chemically amplified EUV resist film. Specifically, FIG. 14 shows the relationship when an ultraviolet exposure amount at the time of forming the SiC film is 200 mJ and 500 mJ.

As shown in the drawing, the higher the ultraviolet exposure amount is during the formation of the SiC film, the less the shape defect of the hole pattern tends to be, that is, the higher the adhesion of the pattern tends to be. In particular, this tendency is conspicuous when the hole diameter is 24 μm or less.

As can be seen from the result shown in FIG. 14, it is possible to reduce the shape defect of the hole pattern by increasing the ultraviolet exposure amount. In addition, although not shown, the same goes for a line pattern.

The ultraviolet exposure amount depends on ultraviolet radiation intensity and time. Since changing the ultraviolet radiation intensity causes a waiting time until this ultraviolet radiation intensity is stabilized, it is desirable to change the ultraviolet exposure amount by changing the ultraviolet radiation time rather than by changing the ultraviolet radiation intensity. However, in case of increasing the ultraviolet radiation time, the time required for the entire processing may be lengthened.

To solve this problem, the control device 4 may determine, according to a defect involved, the ultraviolet radiation time and change the ultraviolet exposure amount, based on conditions related to the wafer W to be processed.

As a specific example, the control device 4 may estimate the number of defects when the ultraviolet rays are radiated for a currently set radiation time from correlation data stored in a storage (not shown), and may decide to increase the radiation time when the estimated number of defects is larger than a target number. Here, the correlation data are data indicating a correlation between the number of defects and the processing conditions regarding the wafer W to be processed, such as a target line width or a hole diameter, a target film thickness, a pattern type, and the like when the currently set radiation time is applied.

Further, the control device 4 may estimate an inspection result (pass or fail) of a product when radiating the ultraviolet rays at the currently set radiation time from correlation data stored in a storage (not shown), and may decide to increase the radiation time when the product is expected to fail the inspection. In this case, the correlation data are data indicating a correlation between the aforementioned processing conditions and a cumulative result of the product when the currently set radiation time is applied.

By determining the ultraviolet radiation time as described above, it is possible to suppress the defects while suppressing the increase in the time required for the entire processing of the wafer W. This technique is advantageous for a pattern size in which the ultraviolet exposure amount has a large effect on the number of defects (for example, when the hole diameter is equal to or less than 24 μm).

In the above-described exemplary embodiment, the etching target film is formed in advance on the wafer W to be processed by the coating and developing apparatus 2. However, the etching target film (for example, a spin-on SiO₂ film) may be formed on the wafer W in the coating and developing apparatus 2.

Further, in the above-described exemplary embodiment, the SoC film is formed on the wafer W in the coating and developing apparatus 2. However, the SoC film may be formed on the wafer W at the outside of the coating and developing apparatus 2.

In the above-described exemplary embodiment, when forming the SiC film, the ultraviolet rays are radiated to the coating film of the SiC film material after the coating film of SiC film material is heated. However, the heating may be performed after the ultraviolet rays are radiated.

Furthermore, in the above-described exemplary embodiment, although the heating of the coating film of the SiC film material and the radiation of the ultraviolet rays to the coating film of the SiC film material are performed in separate units, they may be performed in one and the same unit. In this case, the heating and the ultraviolet radiation may be performed simultaneously.

In addition, the SiC film may be formed by carrying out the above-described dehydration condensation through the heating of the coating film of SiC film material only without performing the radiation of the ultraviolet rays to the coating film of the SiC film material.

### Other Embodiments for Reference

In the above-described exemplary embodiment, the EUV resist film is described to be of a chemically amplified type. However, in the case of radiating the ultraviolet rays in the formation of the SiC film as the base film, the EUV resist film may be a resist film containing a metal oxide, that is, a metal-containing resist film. Even in the case of using the metal-containing resist film, the adhesion between the SiC film and the resist pattern can be improved by radiating the ultraviolet rays to the SiC film. As one of the reasons for this, the following is assumed. That is, when the ultraviolet rays are radiated, hydroxyl groups (OH groups) are generated on the surface of the SiC film, and these OH groups increase the affinity of the metal-containing resist for EUV with the SiC film. As a result, the line width of the portion of the resist pattern in contact with the SiC film, that is, a lower portion of the pattern becomes thicker, and it is assumed that the adhesion between the SiC film and the resist pattern is increased resultantly. Furthermore, the lower portion of the resist pattern may be thinner than an upper portion thereof by being affected by the developing processing. In this case, it is desirable that the line width of the lower portion of the pattern be thicker as described above.

The exemplary embodiments disclosed herein are illustrative in all aspects and do not limit the present disclosure. The above-described exemplary embodiments may be omitted, replaced and modified in various ways without departing from the scope and the spirit of the appended claims.

### EXPLANATION OF CODES

2: Coating and developing apparatus
32: SiC film coating unit
33: Resist coating unit
40: Heat treatment unit
41: Radiation unit
F2: SoC film
F4: SiC film
F5: Resist film
W: Wafer

1. A substrate processing method, comprising:
forming a silicon carbide film on a spin on carbon film formed on a substrate; and
forming a chemically amplified resist film for EUV on the silicon carbide film.

2. The substrate processing method of claim 1,
further comprising:
forming the spin on carbon film on the substrate.

3. The substrate processing method of claim 1,
wherein a main structural portion of the silicon carbide film having silicon atoms and carbon atoms is an aggregate of portions in which the silicon atoms are bonded to each other with the carbon atom therebetween.

4. The substrate processing method of claim 3,
wherein the main structural portion has a structure in which the portions, in which the silicon atoms are bonded to each other with the carbon atom therebetween, are bonded by dehydration condensation.

5. The substrate processing method of claim 3,
wherein in the main structural portion, except atoms that constitute a siloxane bond, an atom bonded to the silicon atom does not include an oxygen atom but includes a carbon atom.

6. The substrate processing method of claim 1,
wherein the forming of the silicon carbide film comprises forming a film of a silicon carbide film material on the spin on carbon film, and, then, radiating an ultraviolet ray to the film of the silicon carbide film material in a low-oxygen atmosphere having an oxygen concentration of 0.1% or less.

7. The substrate processing method of claim 6,
wherein after the film of the silicon carbide film material is formed on the spin on carbon film, the substrate is heated, and then, the ultraviolet ray is radiated to the film of the silicon carbide film material in the low-oxygen atmosphere.

8. The substrate processing method of claim 6,
wherein the silicon carbide film material contains only polycarbosilane as a material containing a portion where a silicon atom and a carbon atom are bonded.

9. The substrate processing method of claim 6, further comprising:
determining radiation time of the ultraviolet ray to the film of the silicon carbide film material based on a condition regarding the substrate to be processed.

10. A substrate processing apparatus, comprising:
a silicon carbide film forming unit configured to form a silicon carbide film on a spin on carbon film formed on a substrate; and
a resist film forming unit configured to form a chemically amplified resist film for EUV on the silicon carbide film.

11. The substrate processing apparatus of claim 10, further comprising:
a spin on carbon film forming unit configured to form the spin on carbon film on the substrate.

12. The substrate processing apparatus of claim 10,
wherein a main structural portion of the silicon carbide film having silicon atoms and carbon atoms is an aggregate of portions in which the silicon atoms are bonded to each other with the carbon atom therebetween.

13. The substrate processing apparatus of claim 12,
wherein the main structural portion has a structure in which the portions, in which the silicon atoms are bonded to each other with the carbon atom therebetween, are bonded by dehydration condensation.

14. The substrate processing apparatus of claim 12,
wherein in the main structural portion, except atoms that constitute a siloxane bond, an atom bonded to the silicon atom does not include an oxygen atom but includes a carbon atom.

15. The substrate processing apparatus of claim 10,
wherein the silicon carbide film forming unit comprises:
a coating unit configured to form a film of a silicon carbide film material on the spin on carbon film; and
a radiation unit configured to form the silicon carbide film by radiating an ultraviolet ray to the film of the silicon carbide film material in a low-oxygen atmosphere with an oxygen concentration of 0.1% or less.

16. The substrate processing apparatus of claim 15,
wherein the silicon carbide film forming unit comprises a heating unit configured to perform heating of the substrate after the film of the silicon carbide film material is formed on the spin on carbon film, and
the radiation unit radiates the ultraviolet ray to the film of the silicon carbide film material in the low-oxygen atmosphere after the heating by the heating unit.

17. The substrate processing apparatus of claim 15,
wherein the silicon carbide film material contains only polycarbosilane as a material containing a portion where a silicon atom and a carbon atom are bonded.

18. The substrate processing apparatus of claim 15,
wherein radiation time of the ultraviolet ray to the film of the silicon carbide film material is determined based on a condition regarding the substrate to be processed.
